(19) United States
(12) Patent Application Publication
(10) Pub. No.: US 2015/0034989 A1
(43) Pub. Date: Feb. 5, 2015

(54) ANISOTROPIC CONDUCTIVE ADHESIVE AND METHOD FOR MANUFACTURING SAME, LIGHT-EMITTING DEVICE AND METHOD FOR MANUFACTURING SAME

(71) Applicant: DEXERIALS CORPORATION, Tokyo (JP)

(72) Inventors: Hidetsugu NAMIKI, Kanuma-shi (JP); Shiyuki KANISAWA, Kanuma-shi (JP); Hideaki UMAKOSHI, Kanuma-shi (JP); Masaharu AOKI, Kanuma-shi (JP); Akira ISHIGAMI, Kanuma-shi (JP)

(21) Appl. No.: 14/515,648

(22) Filed: Oct. 16, 2014

Related U.S. Application Data
(63) Continuation of application No. PCT/JP2013/061318, filed on Apr. 16, 2013.

(30) Foreign Application Priority Data
Apr. 17, 2012 (JP) 2012-094141

(51) Int. Cl. C09J 9/02; C23C 14/14; H01L 33/00; H01L 33/46; H01L 33/62

(52) U.S. Cl. CPC C09J 9/02; H01L 33/46; H01L 33/62; H01L 33/005; C23C 14/14; H01L 2933/0025; H01L 2933/0033; H01L 2933/0066
USPC 257/98; 438/27; 204/192.27; 252/514

(57) ABSTRACT

an anisotropic conductive adhesive which uses conductive particles where a silver-based metal is used as a conductive layer, having high light reflectance and excellent migration resistance is provided. The anisotropic conductive adhesive includes light reflective conductive particles in an insulating adhesive resin. The light reflective conductive particle includes a light reflective metal layer made of a metal alloy including silver, gold and hafnium formed on the surface of a resin particle as a core by sputtering method. The light reflective metal layer is preferably formed having a composition ratio of a silver of at least 50% by weight to at most 80% by weight: a gold of at least 10% by weight to at most 45%: a hafnium of at least 10% by weight to at most 40% by weight, and a total ratio does not exceed 100% by weight.

This application is a continuation of International Application No. PCT/JP2013/61318, filed on Apr. 16, 2014, which claims priority to Japan Patent Application No. 2012-094141, filed on Apr. 17, 2012. The contents of the prior applications are herein incorporated by references in their entireties.

### BACKGROUND

The present invention generally relates to an anisotropic conductive adhesive, and more particularly relates to a technology on an anisotropic conductive adhesive used for flip-chip mounting of semiconductor elements (such as, an LED (light-emitting diode)) on a wiring substrate.

In recent years, attention has been focused on an optical functional element using an LED.

In such an optical functional element, for example, in order to reduce its size, flip-chip mounting is performed in which an LED chip is directly mounted on a wiring substrate.

As the method of performing the flip-chip mounting of an LED chip on a wiring substrate, as shown in FIGS. 4(a) to 4(c), various methods are conventionally known.

FIG. 4(a) shows a mounting method using wire bonding.

In a light-emitting device 101 shown in FIG. 4(a), the LED chip 103 is fixed onto the wiring substrate 102 with a die bonding adhesive 110 and 111 in such a manner that a first and a second electrodes 104 and 105 of an LED chip 103 face the upper side (the opposite side to a wiring substrate 102).

Then, using bonding wires 106 and 108, first and second pattern electrodes 107 and 109 on the wiring substrate 102 are electrically connected to the first and second electrodes 104 and 105 of the LED chip 103, respectively.

FIG. 4(b) shows a mounting method using a conductive paste.

In a light-emitting device 121 shown in FIG. 4(b), the first and second electrodes 104 and 105 are electrically connected to a first and a second pattern electrodes 124 and 125 of the writing substrate 102 by a conductive paste 122 and 123 (such as, a copper paste) for example, in a manner such that the first and second electrodes 104 and 105 of the LED chip 103 face the side of the wiring substrate 102, and the LED chip 103 is adhered onto the wiring substrate 102 with a sealing resin 126 and 127.

FIG. 4(c) shows a mounting method using an anisotropic conductive adhesive.

In a light-emitting device 131 shown in FIG. 4(c), the first and second electrodes 104 and 105 are electrically connected to bumps 132 and 133 provided on the first and second pattern electrodes 124 and 125 of the wiring substrate 102 by conductive particles 135 in the anisotropic conductive adhesive 134 in such a manner that with the first and second electrodes 104 and 105 of the LED chip 103 face the side of the wiring substrate 102, and the LED chip 103 is adhered onto the wiring substrate 102 by an insulating adhesive resin 136 in the anisotropic conductive adhesive 134.

However, there are various problems in the conventional technologies as discussed above.

First, in the mounting method using the wire bonding, because the bonding wires 106 and 108 formed of gold absorb light having, for example, a wavelength of 400 to 500 nm, the light emission efficiency is reduced.

In this method, because the die bonding adhesive 110 and 111 are cured using an oven, the curing time is long, and it is difficult to enhance the production efficiency.

On the other hand, in the mounting method using the conductive paste 122 and 123, because the adhesive force of the conductive paste 122 and 123 alone is low, it is necessary to reinforce with the sealing resin 126 and 127, and the sealing resin 126 and 127 causes light to diffuse into the conductive paste 122 and 123, and light to be absorbed inside the conductive paste 122 and 123, and in the result, the light emission efficiency is reduced.

Furthermore, in this method, because the sealing resin 126 and 127 is cured using an oven, the curing time is long, so that it is difficult to enhance the production efficiency.

On the other hand, in the mounting method using the anisotropic conductive adhesive 134, because the color, of the conductive particles 135 inside the anisotropic conductive adhesive 134 is brown, the color of the insulating adhesive resin 136 becomes brown, and light is absorbed inside the anisotropic conductive adhesive 134, so that the light emission efficiency is reduced.

In order to solve the above-discussed problems, providing an anisotropic conductive adhesive without reducing luminance efficiency is proposed by forming a conductive film using silver (Ag) having high reflection ratio of light and low electric resistance so as to suppress light absorption.

However, because silver is a chemically unstable material, it disadvantageously easily undergoes oxidation and sulfurization, and after thermal compression, migration occurs by energization, and thus, the adhesion strength is disadvantageously degraded by a break in a wiring part and the degradation of an adhesive.

In order to solve the foregoing problems, for example, as discussed in patent document 4, an Ag-based thin film alloy which is excellent in reflectance, corrosion resistance and migration resistance is proposed.

Although coating of the surface of the conductive particles with this Ag-based thin film alloy enhances the corrosion resistance and the migration resistance, when the Ag-based thin film alloy is used as the outermost layer, and nickel, for example, is used as a foundation layer, the reflectance of nickel is lower than that of Ag, and thus, there is a problem that the reflectance of the whole of the conductive particles is reduced, for examples, see JPA No. 2005-120375, JPA No. H05-152464, JPA No. 2003-26763 and JPA No. 2008-266671.

### SUMMARY OF THE INVENTION

The present invention is made by consideration to solve the problems of the conventional technologies as discussed above, an object of the present invention is to provide the technology of an anisotropic conductive adhesive which uses conductive particles where Ag based metal is used as a conductive layer having high light reflectance and excellent migration resistance.

To achieve the above object, according to the present invention, there is provided an anisotropic conductive adhesive including light reflective conductive particles in an insulating adhesive resin, each of the light reflective conductive particles include a light reflective metal layer made of a metal alloy including silver, gold and hafnium formed on a surface of a resin particle as a core.

The present invention is the anisotropic conductive adhesive, wherein the light reflective metal layer in the conductive particle has a composition ratio of a silver of at least 50% by weight to at most 80% by weight: a gold of at least 10% by weight to at most 45%: a hafnium of at least 10% by weight to at most 40% by weight, and a total ratio does not exceed 100% by weight.

The present invention is a method of manufacturing an anisotropic conductive adhesive including light reflective conductive particles in an insulating adhesive resin, wherein each of the light reflective conductive particles include a light reflective metal layer made of a metal alloy including silver, gold and hafnium formed on a surface of a resin particle as a core, and the method comprising the step of forming the light reflective metal layer by a sputtering method.

The present invention is a light-emitting device including a wiring substrate having a connection electrode as a pair; and a light-emitting element having a connection electrode corresponding to the connection electrode of the wiring substrate as a pair, wherein an anisotropic conductive adhesive includes light reflective conductive particles in an insulating adhesive resin, and wherein the light-emitting element is adhered by the anisotropic conductive adhesive, which includes the light reflective metal layer made of a metal alloy including silver, gold and hafnium formed on a surface of a resin particle as a core, onto the wiring substrate, and the connection electrode of the light-emitting element is electrically connected to the corresponding connection electrode of the wiring substrate through the conductive particles of the anisotropic conductive adhesive.

The present invention is a method of manufacturing a light-emitting element, including the steps of preparing a wiring substrate having a connection electrode as a pair and a light-emitting element having a connection electrode corresponding to the connection electrode of the wiring substrate as a pair, arranging an anisotropic conductive adhesive between the light-emitting element and the wiring substrate in a manner such that the connection electrode of the wiring substrate is arranged facing direction to the connection electrode of the light-emitting element, and thermally compressing the light emitting element to the wiring substrate, wherein an anisotropic conductive adhesive includes light reflective conductive particles in an insulating adhesive resin, and wherein the light reflective conductive particle is formed of the light reflective metal layer made of a metal alloy including silver, gold and hafnium formed on a surface of a resin particle as a core.

In the present invention, because the conductive particle of the anisotropic conductive adhesive has a light reflective metal layer made of metal including silver, gold, and hafnium on the surface of the resin particle as a core, accordingly the light reflective metal layer has a reflection rate similar to that of a silver, and thus, it is possible to suppress adsorption of light by the anisotropic conductive adhesive as a minimum.

Consequently, when the anisotropic conductive adhesive of the present invention is used to mount the light-emitting element on the wiring substrate, it is possible to provide the light-emitting device that can efficiently take out light without reducing the light emission efficiency of the light-emitting element.

In the anisotropic conductive adhesive of the present invention, because the light reflective metal layer of the conductive particle includes gold and hafnium of which migration does not easily occur is, it is possible to enhance migration resistance.

On the other hand, according to the method of the present invention, because the light-emitting device which provides the significant effects discussed above can be manufactured by the arrangement of the anisotropic conductive adhesive and the simple and rapid thermal compression process, it is possible to significantly enhance the production efficiency.

According to the present invention, it is possible to provide the technology of an anisotropic conductive adhesive using conductive particles where Ag based metal is used as a conductive layer and having high light reflectance and excellent migration resistance.

### BRIEF DESCRIPTION OF DRAWINGS

FIG. 1(a) is a cross-sectional view schematically showing the configuration of an anisotropic conductive adhesive according to the present invention.

FIG. 1(b) shows an enlarged cross-sectional view showing the configuration of a conductive particle (No. 1) used in the present invention.

FIG. 1(c) is a an enlarged cross-sectional view illustrating a configuration of a conductive particle (No. 2) used in the present invention.

FIG. 1(d) is a cross-sectional view showing the configuration of an example of a light-emitting device according to the present invention.

FIGS. 2(a) to 2(c) are Diagrams showing an embodiment of a process of manufacturing the light-emitting device according to the present invention.

FIG. 3 is a graph illustrating a relation between a reflection rate of an anisotropic conductive adhesive and a wavelength of an incident light.

FIG. 4(a) are a diagram showing a mounting method using wire bonding.

FIG. 4(b) is a diagram showing a mounting method using a conductive paste.

FIG. 4(c) is a diagram showing a mounting method using the anisotropic conductive adhesive.

### DETAILED DESCRIPTION OF THE INVENTION

A preferred embodiment of the present invention will be discussed in detail below with reference to accompanying drawings.

In particular, an anisotropic conductive adhesive in paste form can be suitably applied to the present invention.

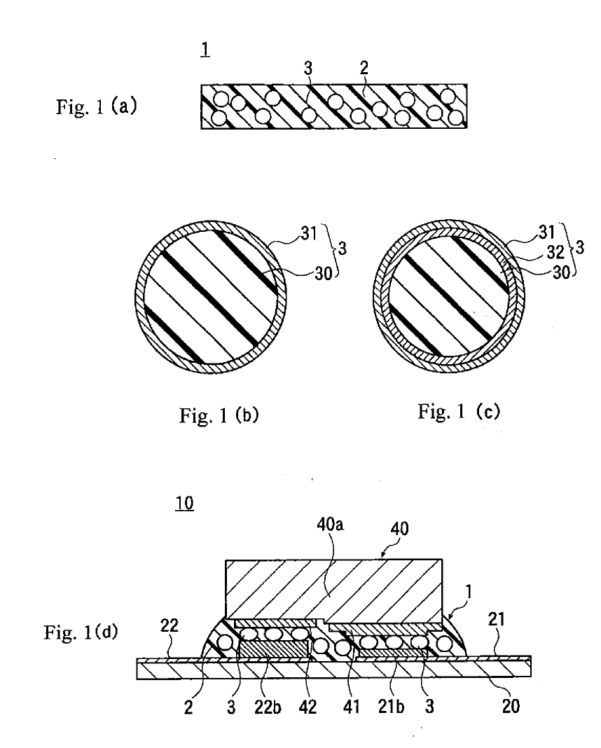

FIG. 1(a) is a cross-sectional view schematically showing the structure of an anisotropic conductive adhesive according to the present invention, FIGS. 1(b) and 1(c) are the enlarged cross-sectional view showing the structure of conductive particles used in the present invention, and FIG. 1(d) is a cross-sectional view showing the structure of an embodiment of a light-emitting device according to the present invention.

As shown in FIG. 1(a), in the anisotropic conductive adhesive 1 of the present invention, a plurality of conductive particles 3 which are dispersed in an insulating adhesive resin 2.

In the present invention, the insulating adhesive resin 2 is not particularly limited, however, in terms of superiority of transparency, adhesion, heat resistance, mechanical strength and electrical insulation, a composition containing an epoxy resin and a curing agent thereof can be preferably used.

Specifically, examples of the epoxy resin include an alicyclic epoxy compound, a heterocyclic epoxy compound and a hydrogenated epoxy compound. As the alicyclic epoxy compound, an alicyclic epoxy compound having at least two epoxy groups within a molecule is preferably used. It may be liquid form or solid form. Specific examples include glycidyl hexahydrobisphenol A, 3,4-epoxycyclohexenylmethyl-3′ and 4′-epoxycyclohexenecarboxylate. Among them, because optical transparency suitable for, for example, the mounting of an LED element can be acquired in the cured material, and rapid curing is excellently achieved, glycidyl hexahydrobisphenol A, 3,4-epoxycyclohexenylmethyl-3′ or 4′-epoxycyclohexenecarboxylate can be preferably used.

As the heterocyclic epoxy compound, an epoxy compound having a triazine ring can be used, and 1,3,5-tris(2,3-epoxypropyl)-1,3,5-triazine-2,4,6-(1H,3H,5H)-trione can be particularly preferably used.

As the hydrogenated epoxy compound, a hydrogen additive of the alicyclic epoxy compound or the heterocyclic epoxy compound discussed above or another known hydrogenated epoxy resin can be used.

As long as the effects of the present invention are not degraded, in addition to these epoxy compounds, another epoxy resin may be used together. Examples thereof include the following known epoxy resins: glycidyl ether 1 glycerin which is obtained by making epichlorohydrin react with a polyhydric phenol such as bisphenol A, bisphenol F, bisphenol S, tetramethyl bisphenol A, diaryl bisphenol A, hydroquinone, catechol, resorcin, cresol, tetrabromobisphenol A, trihydroxy biphenyl, benzophenone, bis-resorcinol, bisphenol hexafluoroacetone, tetramethyl bisphenol A, tetramethyl bisphenol F, tris(hydroxyphenyl)methane, bixylenol, phenol novolac or cresol novolac; polyglycidyl ether lp-oxybenzoic acid which is obtained by making epichlorohydrin react with an aliphatic polyhydric alcohol such as neopentyl glycol, ethylene glycol, propylene glycol, thylene glycol, hexylene glycol, polyethylene glycol or polypropylene glycol; glycidyl ether ester 1 phthalic acid which is obtained by making epichlorohydrin react with a hydroxycarboxylic acid such as, β-oxy naphthoic acid; polyglycidyl ester 1 aminophenol which is obtained from a polycarboxylic acid such as methylphthalic acid, isophthalic acid, terephthalic acid, tetrahydro phthalic acid, endomethylene tetrahydrophthalic acid, endomethylene hexahydrophthalic acid, trimellitic acid or polymerized fatty acid; glycidylamino glycidyl ester 1 aniline which is obtained from glycidylamino glycidyl ether 1 amino benzoic acid obtained from aminoalkylphenol; and glycidyl amine 1 epoxy polyolefin that is obtained from toluidine, tribromoaniline, xylylenediamine, diaminocyclohexane, bis aminomethyl cyclohexane, 4,4′-diaminodiphenyl methane or 4,4′-diaminodiphenyl sulfone. As the curing agent, an acid anhydride, an imidazole compound, dicyan or the like can be used. Among them, an acid anhydride which is unlikely to discolor a curing agent, in particular, an alicyclic acid anhydride curing agent, can be preferably used. Specifically, methylhexahydrophthalic anhydride or the like can be preferably used.

When an alicyclic epoxy compound and an alicyclic acid anhydride curing agent are used together, because there is a tendency that when the amount of alicyclic acid anhydride curing agent used is excessively low, the amount of uncured epoxy is increased whereas when the amount of alicyclic acid anhydride curing agent used is excessively high, the effect of the excessive amount of curing agent facilitates the corrosion of an adherend material, with respect to 100 weight parts of the alicyclic epoxy compound, 80 to 120 weight parts can be preferably used, and 95 to 105 weight parts can be more preferably used.

in order to increase the reflection rate of whole anisotropic conductive adhesive 1, the insulating adhesive resin 2 is preferably used, the insulating adhesive resin 2 having a reflection rate of 30% or more at a peak wavelength 460 nm, which is a peak wavelength of a blue light, for example, after the anisotropic conductive adhesive is cured.

As shown in FIG. 1(b), the conductive particle 3 of the present invention includes a resin particle 30 as a core, a light reflective metal layer 31 is formed on the surface of the resin particle 30.

In the present invention, although the resin particle 30 is not particularly limited, in order to obtain a high reliability of conductivity, it is possible to preferably use, for example, a resin particle formed of cross-linked polystyrene, benzoguanamine, nylon or PMMA (polymethacrylate) or the like.

Although the size of the resin particle 30 is not particularly limited in the present invention, in order to obtain a high reliability of conductivity, it is possible to preferably use the resin particle having an average particle diameter of 3 μm to 5 μm.

As shown in FIG. 1C, lower plating layer 32 of a metal such as a nickel and a gold may be formed on the surface of the resin particle in order to obtain high adhesion to the light reflective metal layer 31.

The material of the light reflective metal layer 31 is made of alloy including silver (Ag), gold (Au), hafnium (Hf).

In this case, it is preferable to use silver having a purity (proportion in a metal component) of at least 98 weight %.

In the present invention, although the method of forming the light reflective metal layer 31 is not particularly limited, in order to have uniform coating of silver alloy, it is preferable to adopt a sputtering method.

The sputtering method is one of the methods of forming a thin film on an object, and is performed in vacuum containing a sputter gas. In the sputtering method, with the interior of a container being made vacuum ambience, a voltage is applied between an object to be processed and a sputtering target so as to generate grow discharge. Electrons and ions generated in this way are made to collide with the target at high speed, and thus, the particles of the target material are forced out, and the particles (sputter particles) are adhered to the surface of the object to be film-formed, and then, a thin film is formed.

Here, as a method for forming a thin film on fine particles by the sputtering as in the present invention, it is preferable to set the fine particles dispersed as primary particles in a container inside a device and to rotate the container to make the fine particles flow. In other words, by performing the sputtering on the fine particles in its fluidized state, it is possible to make the sputter particles of the target material collide with the entire surface of the individual fine particles so as to form a thin film over the entire surface of the individual fine particles.

As the sputtering method applied to the present invention, it is possible to adopt a known sputtering method (such as, a bipolar sputtering method, a magnetron sputtering method, a high-frequency sputtering method or a reactive sputtering method).

In the present invention, although the composition ratio of the light reflective metal layer 31 is not limited to a particular ratio, the following composition ratio is preferable for ensuring desired reflection rate and migration resistance: the ratio of a silver has a range of 50% by weight or more to 80% by weight or less, the ratio of a gold has a range of 10% by weight or more to 45% by weight or less, the ratio of a hafnium has a range 10% by weight or more to 40% by weight or less, then whole ratio is adjusted not to exceed 100% by weight.

Note that a high gold ratio may result in decrease in reflection rate, a high hafnium ratio may results in decrease in conductivity, while low ratio of a gold and a hafnium may result in decrease in migration resistance.

In the present invention, adjustment of the composition ratio in the light reflective metal layer 31 can be achieved by performing sputtering with a target material (not illustrated) of an alloy including a silver, a gold, and a hafnium, the composition ratio of the target material is adjusted, for example. Note that, the light reflective metal layer 31 may also include, for example, a bismuth, and a neodym.

In the present invention, although the thickness of the light reflective metal layer 31 is not particularly limited, in order to acquire a desired reflectance, it is preferable to set the thickness at least 0.1 μm.

In the present invention, although a content amount of the conductive particles 3 in the insulating adhesive resin 2 is not particularly limited, with consideration given to the acquisition of light reflectance, migration resistance and insulation, it is preferable to contain at least 1 weight part and at most 100 weight parts of the conductive particles 3 in 100 weight parts of the insulating adhesive resin 2.

In order to manufacture the anisotropic conductive adhesive 1 of the present invention, for example, the conductive particles 3 dispersed in a predetermined solvent are added to a solution in which a predetermined epoxy resin or the like is solved, and they are mixed so as to prepare a binder paste.

Here, when an anisotropic conductive adhesive film is manufactured, for example, a separation film (such as, a polyester film) is coated with this binder paste, and after drying, a cover film is laminated, and thus, the anisotropic conductive adhesive film having a desired thickness is obtained.

On the other hand, as shown in FIG. 1(d), the light-emitting device 10 of the present embodiment includes, for example, a wiring substrate 20 made of ceramic and a light-emitting element 40 which is mounted on the wiring substrate 20.

In the present embodiment, the first and second connection electrodes 21 and 22 are formed by, for example, silver plating into a predetermined pattern on the wiring substrate 20, as a pair of connection electrodes.

For example, terminal portions 21b and 22b which are formed of stud bumps and having convex shape are respectively provided on the adjacent end portions of the first and second connection electrodes 21 and 22.

On the other hand, as the light-emitting element 40, for example, an LED (light-emitting diode) which emits visible light having a peak wavelength of at least 400 nm and at most 500 nm is used.

In the present invention, in particular, an LED for blue color having a peak wavelength of around 460 nm can be suitably used.

In the light-emitting element 40, its main body portion 40a is formed in the shape of, for example, a rectangular parallelepiped, and on one surface, first and second connection electrodes 41 and 42 which are an anode electrode and a cathode electrode are provided.

Sizes and shapes are set in a manner such that when the terminal portions 21b and 22b of the first and second connection electrodes 21 and 22 of the wiring substrate 20 and the first and second connection electrodes 41 and 42 of the light-emitting element 40 are arranged opposite each other, the connection portions thereof face each other.

The light-emitting element 40 is adhered onto the wiring substrate 20 by the cured anisotropic conductive adhesive 1 discussed above.

Furthermore, the first and second connection electrodes 41 and 42 of the light-emitting element 40 are electrically connected to the corresponding first and second connection electrodes 21 and 22 (the terminal portions 21b and 22b) of the wiring substrate 20, respectively, through the conductive particles 3 of the anisotropic conductive adhesive 1.

Specifically, the first connection electrode 41 of the light-emitting element 40 is electrically connected to the terminal portion 21b of the first connection electrode 21 of the wiring substrate 20 by contact with the conductive particles 3, and the second connection electrode 42 of the light-emitting element 40 is electrically connected to the terminal portion 22b of the second connection electrode 22 of the wiring substrate 20 by contact with the conductive particles 3.

On the other hand, the first connection electrode 21 of the wiring substrate 20 and the first connection electrode 41 of the light-emitting element 40, and the second connection electrode 22 of the wiring substrate 20 and the second connection electrode 42 of the light-emitting element 40 are insulated from each other by the insulating adhesive resin 2 in the anisotropic conductive adhesive 1.

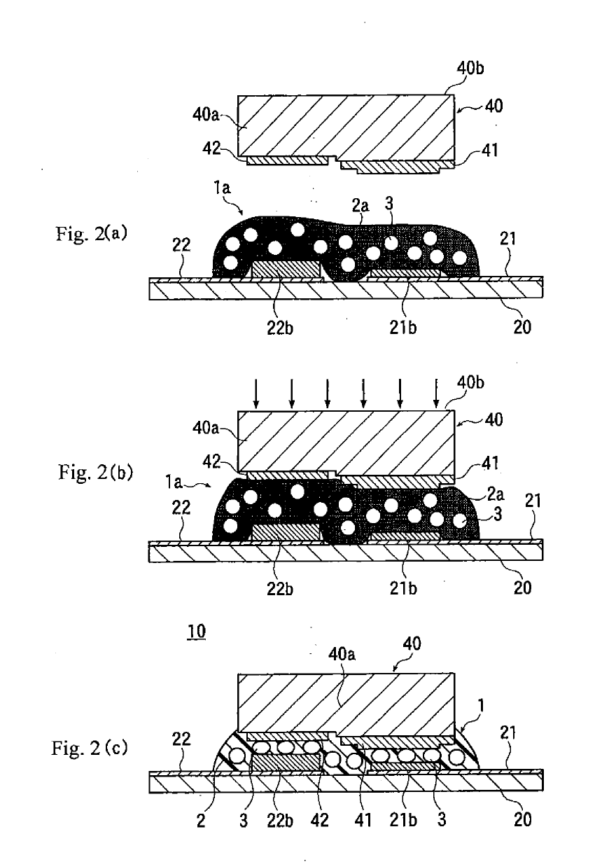

FIGS. 2(a) to 2(c) are diagrams showing an embodiment of a process for manufacturing the light-emitting device of the present invention.

First, as shown in FIG. 2(a), the wiring substrate 20 having a pair of first and second connection electrodes 21 and 22 and the light-emitting element 40 having the first and second connection electrodes 41 and 42 which are corresponding to the first and second connection electrodes 21 and 22 of the wiring substrate 20 are prepared.

Then, in a state where the terminal portions 21b and 22b of the first and second connection electrodes 21 and 22 of the wiring substrate 20 and the first and second connection electrodes 41 and 42 of the light-emitting element 40 are arranged opposite each other, an uncured anisotropic conductive adhesive 1a in paste form is arranged so as to cover the terminal portions 21b and 22b of the first and second connection electrodes 21 and 22 of the wiring substrate 20.

For example, when the uncured anisotropic conductive adhesive 1a is formed in the shape of a film, the uncured anisotropic conductive adhesive 1a is adhered, for example, with an adhering device (not shown), to a predetermined position of the surface on the side where the first and second connection electrodes 21 and 22 of the wiring substrate 20 are provided.

As shown in FIG. 2(b), the light-emitting element 40 is placed on the uncured anisotropic conductive adhesive 1a, and the surface of the light emission side of the light-emitting element 40, that is, the surface 40b which is the opposite side to the side where the first and second connection electrodes 41 and 42 are provided is pressurized and heated with a thermal compression head (not shown) at predetermined pressure and temperature.

Thereby, the insulating adhesive resin 2a of the uncured anisotropic conductive adhesive 1a is cured, and as shown in FIG. 2(c), the light-emitting element 40 is adhered and fixed onto the wiring substrate 20 by the adhesion of the cured anisotropic conductive adhesive 1.

In this thermal compression process, a plurality of conductive particles 3 make contact with the terminal portions 21b and 22b of the first and second connection electrodes 21 and 22 of the wiring substrate 20 and the first and second connection electrodes 41 and 42 of the light-emitting element 40, and they are pressurized, and in the result, the first connection electrode 41 of the light-emitting element 40 and the first connection electrode 21 of the wiring substrate 20, and the second connection electrode 42 of the light-emitting element 40 and the second connection electrode 22 of the wring substrate 20 are electrically connected, respectively.

On the other hand, the first connection electrode 21 of the wiring substrate 20 and the first connection electrode 41 of the light-emitting element 40, and the second connection electrode 22 of the wiring substrate 20 and the second connection electrode 42 of the light-emitting element 40 are insulated from each other by the insulating adhesive resin 2 in the anisotropic conductive adhesive 1.

Then, by the above-identified process, the intended light-emitting device 10 is obtained.

In the present embodiment as discussed above, because the conductive particle 3 of the anisotropic conductive adhesive 1 is made by forming the light reflective metal layer 31 made of the alloy including silver, gold and hafnium on the surface of the resin particle 30 as a core, and furthermore, the alloy having high reflectance similar to silver, so that it is possible to minimize the absorption of light by the anisotropic conductive adhesive 1.

Consequently, when the anisotropic conductive adhesive 1 of the present embodiment is used to mount the light-emitting element 40 on the wiring substrate 20, it is possible to provide the light-emitting device 10 that can efficiently extract light without reducing the light emission efficiency of the light-emitting element 40.

In the anisotropic conductive adhesive 1 of the present embodiment, the light reflective layer 31 made of the silver alloy where migration is unlikely to occur is formed on the surface of the conductive particle 3, and thus, it is possible to enhance migration resistance.

On the other hand, in the method according to the present embodiment, the light-emitting device 10 can be manufactured by the simple and rapid processes, and by the process of arranging the anisotropic conductive adhesive 1 and the thermal compression process, it is possible to significantly enhance the production efficiency.

The present invention is not limited to the embodiment discussed above, and various modifications can be performed.

For example, the light-emitting device 10 shown in FIG. 1(c) and FIGS. 2(a) to (c) is schematically shown by simplifying its shape and size, so that the shapes, the sizes, the numbers and the like of the wiring substrate and the connection electrodes of the light-emitting element can be changed as necessary.

The present invention can be applied not only to, for example, the light-emitting element for blue color having a peak wavelength of around 460 nm but also to light-emitting elements having various peak wavelengths.

However, the present invention is most effective when the present invention is applied to the light-emitting element having a peak wavelength of around 460 nm.

### EXAMPLES

Although the present invention will be specifically discussed below using examples and comparative examples, the present invention is not limited to the following examples.

<Preparation of Adhesive Composition>

An adhesive composition is prepared using 100 weight parts of an epoxy resin (sold under the name “CPEL2021P” made by Daicel chemical Industries, Ltd.), 100 weight parts of methylhexahydrophthalic anhydride (sold under the name “MH-700” made by New Japan Chemical Co., Ltd.) as a curing agent, 2 weight parts of a curing accelerator (sold under the name “2E4MZ” made by Shikoku Chemicals Corporation) and toluene as a solvent.

<Preparation of Conductive Particles>

### Example Particle 1

A light reflective metal layer made of silver alloy (silver:gold:hafnium=54.5:27.3:18.2) having a thickness of 0.2 μm is formed by a sputtering method on the surface of resin particles (sold under the name “Art Pearl J-6P” made by Negami Chemical Industrial Co., Ltd.) made of a cross-linked acrylic resin having an average particle diameter of 5 μm.

In this case, as a sputtering apparatus, a powder sputtering apparatus made by Kyouritu Ltd. is used, and as a sputtering target, an Ag—Au—Hf alloy target made by a dissolution and casting method is used.

### Example Particle 2

An example particle 2 was manufactured with the same condition as the condition of the example particle 1 except the composition ratio of the light reflective metal layer (silver:gold:hafnium=50:10:40).

### Example Particle 3

An example particle 3 was manufactured with the same condition as the condition of the example particle 1 except the composition ratio of the light reflective metal layer (silver:gold:hafnium=50:40:10).

### Example Particle 4

An example particle 4 was manufactured with the same condition as that of the example particle 1 except the composition ratio of the light reflective metal layer (silver:gold:hafnium=80:10:10).

### Example Particle 5

An example particle 5 was manufactured with the same condition as the condition of the example particle 1 except using a resin particle made of an acrylic resin having an average particle size of 4.6 μm (manufactured by Nippon Chemical Industrial Co.), on which a nickel plating layer having a thickness 0.2 μm is formed.

### Comparative Example Particle 1

A comparative example particle 1 was manufactured with the same condition as the condition of the example particle 1 except forming a light reflective metal layer of gold on the surface of the resin particle.

### Comparative Example Particle 2

A comparative example particle 2 was manufactured with the same condition as the condition of the example particle 1 except forming a light reflective metal layer of silver on the surface of the resin particle.

### Comparative Example Particle 3

A comparative example particle 3 was manufactured with the same condition as the condition of the example particle 1 except the composition ratio of the light reflective metal layer (silver:gold:hafnium=98:1:1).

### Comparative Example Particle 4

A comparative example particle 4 was manufactured with the same condition as the condition of the example particle 1 except the composition ratio of the light reflective metal layer (silver:gold:hafnium=30:5:65).

### Comparative Example Particle 5

A comparative example particle 5 was manufactured with the same condition as the condition of the example particle 1 except the composition ratio of the light reflective metal layer (silver:gold:hafnium=30:62:8).

<Production of Anisotropic Conductive Adhesive>

15 weight parts of each of example particles 1 to 5 and comparative example particles 1 to 3 are mixed with 100 weight parts of the adhesive composition discussed above (except the solvent), and thus anisotropic conductive adhesives of examples 1 to 5 and comparative examples 1 to 5 are obtained.

<Evaluation>

(1) Reflectance

The anisotropic conductive adhesives of examples 1 to 5 and comparative examples 1 to 5 are applied onto smooth plates in a manner such that each thickness after being dried is 100 μm, and are cured by heating for 1 minute at 200 degree Celsius, and thus, samples for reflectance measurement are produced.

For each of the samples, a reflectance is measured at a wavelength of 460 nm, which is a blue wavelength by a spectroscopic colorimeter (CM-3600 made by Konica Minolta, Inc.). The results thereof are shown in table 1.

(3) Fabrication of LED Mounted Sample and Evaluation of Total Luminous Flux

The anisotropic conductive adhesives of the examples 1 to 5 and the comparative examples 1 to 5 are placed on a smoothed gold bump placed on the wiring board. The wiring board has a pitch of 100 μm between the electrodes, and nickel/gold plated layer=5.0 μm/0.3 μm. And the thickness of the gold bump is 15 μm.

A blue light LED chips (Vf=3.2 V (If=20 mA)) is placed and aligned on the above-described wiring board, then thermal compression bonding is performed with a temperature of 200 degree Celsius, and a pressure of 1 kg per one chip for 20 seconds to fabricate the LED mounted samples of the examples 1 to 5 and the comparative examples 1 to 5.

The total luminous flux of the LED mounted samples of the examples 1 to 5 and the comparative examples 1 to 5 are measured under the condition of a constant current control of If=20 mA using a sphere type total luminous flux measurement system (LE-2100 manufactured by Otsuka Electronics Co). The Table 1 illustrates the results.

(3) Migration Resistance

On each of the above-discussed LED mounted samples using anisotropic conductive adhesives of examples 1 to 5 and comparative examples 1 to 5, a high-temperature and high-humidity test of applying energization in an environment of a temperature of 85° C. and a relative humidity of 85% RH is performed for 500 hours. After the test, the total luminous flux of each sample was measured, and each change rate was calculated. The results thereof are shown in table 1.

(4) Conduction Reliability

In the migration resistance test discussed above, a case where the continuity is determined to be broken (open) is represented by “◯” in evaluation, and a case where a short-circuit occurs in a part of a measurement pattern is represented by “Δ” in evaluation. The results thereof are shown in table 1.

TABLE 1
Configuration and evalucation results of examples 1 to 5 and comparative examples 1 to 5

| | | | | | | | | Compar- | Compar- | Compar- | Compar- | Compar- |
|---|---|---|---|---|---|---|---|---|---|---|---|---|
| | | | Exam- | Exam- | Exam- | Exam- | Exam- | ative | ative | ative | ative | ative |
| | | | ple 1 | ple 2 | ple 3 | ple 4 | ple 5 | example 1 | example 2 | example 3 | example 4 | example 5 |
| | | | acrylic | acrylic | acrylic | acrylic | acrylic | acrylic | acrylic | acrylic | acrylic | acrylic |
| Core particle | | Type | resin | resin | resin | resin | resin | resin | resin | resin | resin | resin |
| | | Particle size | 5 | 5 | 5 | 5 | 5 | 5 | 5 | 5 | 5 | 5 |
| | | (μ m) | | | | | | | | | | |
| Composition ratio | | Ag | 54.5 | 50 | 50 | 80 | 60 | — | 100 | 98 | 30 | 30 |
| of reflective metal | | Au | 27.3 | 10 | 40 | 10 | 30 | 100 | — | 1 | 5 | 62 |
| layer (wt %) | | Hf | 18.2 | 40 | 10 | 10 | 20 | — | — | 1 | 65 | 8 |
| Particle | | Color | gray | gray | gray | gray | gray | brown | gray | gray | gray | gray |
| appearance | | | | | | | | | | | | |
| Reflection rate*¹ | | (%) | 45 | 40 | 35 | 50 | 50 | 8 | 55 | 52 | 35 | 15 |
| Optical | Total | initial | 330 | 300 | 280 | 360 | 370 | 200 | 390 | 370 | 280 | 230 |
| property | luminous | | | | | | | | | | | |
| | flux (mlm) | | | | | | | | | | | |
| | Change | 85° C. 85% | 0 | 0 | 0 | 0 | 0 | 0 | −20% | −15% | 0 | 0 |
| | rate of total | RH-500 h ON | | | | | | | | | | |
| | lumious flux | | | | | | | | | | | |
| | after the the | | | | | | | | | | | |
| | test (%) | | | | | | | | | | | |
| Electrical | Conductieve | Initial | ∘ | ∘ | ∘ | ∘ | ∘ | ∘ | ∘ | ∘ | Δ | ∘ |
| property | reliability | 85° C. 85% | ∘ | ∘ | ∘ | ∘ | ∘ | ∘ | x | x | Δ | ∘ |
| | | RH-500 h ON | | | | | | | | | | |

Note:
“reflection rate” is a ratio of a light amount of a reflection light relative to an incident light having a wavelength of 460 mm.

As can be seen clearly from the Table 1, the resin cured compound including the anisotropic conductive adhesive of the example 1 with a light reflective metal layer of silver:gold:hafnium=54.5:27.3:18.2 exhibited a reflection rate of 45%, and the LED mounted sample thereof exhibited a total luminous flux of 330 mlm. This exhibited higher values than the values of the comparative example 1 using a conductive particle, which includes a resin particle having a light reflective metal layer made of a gold formed on its surface, and this shows increase in extraction efficiency of a light emitted from the LED mounted sample.

Further, the initial total luminous flux and electrical property did not change after the high temperature and high humidity test which lasted 500 hours. These results show that the color change of the conductive particles and the migration did not occur.

### Example 2

The resin cured compound including the anisotropic conductive adhesive of the example 2 with a light reflective metal layer of silver:gold:hafnium=50:10:40 exhibited a reflection rate of 40%, and the LED mounted sample thereof exhibited a total luminous flux of 300 mlm. This exhibited higher values than the values of the comparative example 1 using a conductive particle, which includes a resin particle having a light reflective metal layer made of a gold formed on its surface, and this which shows increase in extraction efficiency of a light emitted from the LED mounted sample. Further, the initial total luminous flux and electrical property did not change after the high temperature and high humidity test which lasted 500 hours. These results show that the color change of the conductive particles and the migration did not occur.

### Example 3

The resin cured compound including the anisotropic conductive adhesive of the example 3 with a light reflective metal layer of silver:gold:hafnium=50:40:10 exhibited a reflection rate of 35%, and the LED mounted sample thereof exhibited a total luminous flux of 280 mlm. This exhibited higher values than the values of the comparative example 1 using a conductive particle including a resin particle having a light reflective metal layer made of a gold formed on its surface, and this shows increase in extraction efficiency of a light emitted from the LED mounted sample. Further, the initial total luminous flux and electrical property did not change after the high temperature and high humidity test which lasted 500 hours. These results shows that the color change of the conductive particles and the migration did not occur.

### Example 4

The resin cured compound including the anisotropic conductive adhesive of the example 4 with a light reflective metal layer of silver:gold:hafnium=80:10:10 exhibited a reflection rate of 50%, and the LED mounted sample thereof exhibited a total luminous flux of 360 mlm. This exhibited higher values than those of the comparative example 1 using a conductive particle which includes a resin particle the surface of which is covered with a light reflective metal layer of a gold, and this shows increase in extraction efficiency of a light emitted from the LED mounted sample. Further, the initial total luminous flux and electrical property did not change after the high temperature and high humidity test which lasted 500 hours. These results shows that the color change of the conductive particles and the migration did not occur.

### Example 5

The resin cured compound including the anisotropic conductive adhesive of the example 5 with a nickel-plated resin particle having the surface of which was covered with a light reflective metal layer of silver:gold:hafnium=54.5:27.3:18.2 exhibited a reflection rate of 50%, and the LED mounted sample thereof exhibited a total luminous flux of 370 mlm. This exhibited higher values than the values of the comparative example 1 using a conductive particle which includes a resin particle having the surface of which is covered with a light reflective metal layer of a gold, and this shows increase in extraction efficiency of a light emitted from the LED mounted sample. Further, the initial total luminous flux and electrical property did not change after the high temperature and high humidity test which lasted 500 hours. These results show that the color change of the conductive particles and the migration did not occur.

### Comparative Example 1

The resin cured compound including the anisotropic conductive adhesive of the comparative example 1 with a resin particle having the surface of which was covered with a light reflective metal layer of a gold exhibited a reflection rate of 8%, and the LED mounted sample thereof exhibited a total luminous flux of 200 mlm. This exhibited lower extraction efficiency of a light emitted from the LED chip than that of the anisotropic conductive adhesives of examples 1 to 5. This may be because a light emitted from the LED chip was absorbed by gold on the surface of the conductive particle. Comparative Example 2

The resin cured compound including the anisotropic conductive adhesive of the comparative example 2 with a resin particle the surface of which was covered with a light reflective metal layer of a silver exhibited a reflection rate of 55%, and the LED mounted sample thereof exhibited a total luminous flux of 390 mlm. This exhibited high extraction efficiency of a light emitted from the LED chip. The total luminous, however, flux decreased by 20% after the high temperature and high humidity test which lasted 500 hours. Further, after the above-described test, a small leak (short circuit) was detected, and an external observation with a microscope found the color change of the conductive particle.

### Comparative Example 3

The resin cured compound including the anisotropic conductive adhesive of the comparative example 3 with a light reflective metal layer of silver:gold:hafnium=98:1:1 exhibited a reflection rate of 52%, and the LED mounted sample thereof exhibited a total luminous flux of 370 mlm. This exhibited high extraction efficiency of a light emitted from the LED chip. The total luminous flux, however, decreased by 15% after the high temperature and high humidity test which lasted 500 hours. Further, after the above-described test, a small leak (short circuit) was detected, and an external observation with a microscope found the color change of the conductive particle.

### Comparative Example 4

The resin cured compound including the anisotropic conductive adhesive of the comparative example 4 with a light reflective metal layer of silver:gold:hafnium=30:5:65 exhibited a reflection rate of 35%, and the LED mounted sample thereof exhibited a total luminous flux of 280 mlm. This exhibited the same extraction efficiency of alight emitted from the LED chip as that of the example 3. A large conduction resistance, however, was found at an initial stage and after the high temperature and high humidity test which lasted 500 hours.

### Comparative Example 5

The resin cured compound including the anisotropic conductive adhesive of the comparative example 5 with a light reflective metal layer of silver:gold:hafnium=30:62:8 exhibited a reflection rate of 15%, and the LED mounted sample thereof exhibited a total luminous flux of 230 mlm. This exhibited lower extraction efficiency of a light from the LED chip than that of the examples 1 to 5.

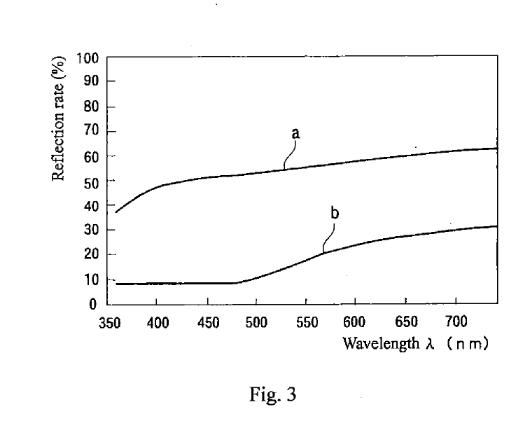

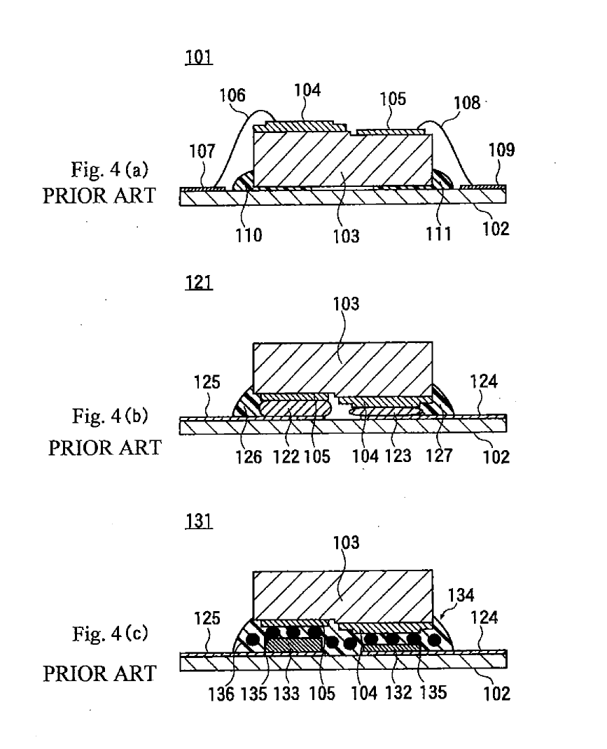

FIG. 3 is a graph showing a relationship between a reflection rate of an anisotropic conductive adhesive and a wavelength of an incident light, and the values are measured using the above-described luminous flux measurement system. In the graph of FIG. 3, a curved line “a” indicates the reflection rate of the anisotropic conductive adhesive of the example 5, while a curved line “b” indicates the reflection rate of the anisotropic conductive adhesive of the comparative example 1.

As can be seen from FIG. 3, the anisotropic conductive adhesive of the example 5 with a nickel-plated resin particle having the surface of which is covered with a light reflective metal layer of silver:gold:hafnium=54.5:27.3:18.2 has a reflection rate which is 30% or higher than that of the anisotropic conductive adhesive of the comparative example 1 with a resin particle having the surface of which is covered with a light reflective metal layer of a gold even within a wavelength range of at least 360 nm to at most 500 nm.

As shown in the above results, according to the present invention, it is possible to obtain an anisotropic conductive adhesive for light-emitting elements which has a high light reflectance and an excellent migration resistance.

### LIST OF REFERENCE NUMERALS

1 anisotropic conductive adhesive
2 insulating adhesive resin
3 conductive particle
10 light-emitting device
20 wiring substrate
21 first connection electrode
22 second connection electrode
30 resin particle
31 light reflective metal layer
32 lower plating layer
40 light-emitting element
41 first connection electrode
42 second connection electrode

1. An anisotropic conductive adhesive comprising light reflective conductive particles in an insulating adhesive resin,
wherein each of the light reflective conductive particles includes a light reflective metal layer made of a metal alloy including silver, gold and hafnium formed on a surface of a resin particle as a core.

2. The anisotropic conductive adhesive according to claim 1,
wherein the light reflective metal layer in the conductive particle has a composition ratio of a silver of at least 50% by weight to at most 80% by weight: a gold of at least 10% by weight to at most 45%: a hafnium of at least 10% by weight to at most 40% by weight, and a total ratio does not exceed 100% by weight.

3. A method of manufacturing an anisotropic conductive adhesive including light reflective conductive particles in an insulating adhesive resin,
wherein each of the light reflective conductive particles includes a light reflective metal layer made of a metal alloy including silver, gold and hafnium formed on a surface of a resin particle as a core, and
the method comprising the step of forming the light reflective metal layer by a sputtering method.

4. A light-emitting device comprising:
a wiring substrate having a connection electrode as a pair; and
a light-emitting element having a connection electrode corresponding to the connection electrode of the wiring substrate as a pair,
wherein an anisotropic conductive adhesive includes light reflective conductive particles in an insulating adhesive resin, and
wherein the light-emitting element is adhered by the anisotropic conductive adhesive onto the wiring substrate, and the connection electrode of the light-emitting element is electrically connected to the corresponding connection electrode of the wiring substrate through the conductive particles of the anisotropic conductive adhesive, and
wherein each of the light reflective conductive particles includes a light reflective metal layer made of a metal alloy including silver, gold and hafnium formed on a surface of a resin particle as a core.

5. A method of manufacturing a light-emitting element,
comprising the steps of:
preparing a wiring substrate having a connection electrode as a pair and a light-emitting element having a connection electrode corresponding to the connection electrode of the wiring substrate as a pair,
arranging an anisotropic conductive adhesive between the light-emitting element and the wiring substrate in a manner such that the connection electrode of the wiring substrate is arranged facing direction to the connection electrode of the light-emitting element, and
thermally compressing the light emitting element to the wiring substrate,
wherein an anisotropic conductive adhesive includes light reflective conductive particles in an insulating adhesive resin, and
wherein each of the light reflective conductive particles is formed of a light reflective metal layer made of a metal alloy including silver, gold and hafnium formed on a surface of a resin particle as a core.
